(19) United States
(12) Patent Application Publication
(10) Pub. No.: US 2026/0096428 A1
(43) Pub. Date: Apr. 2, 2026

(54) NON-ISOLATED DIRECT COOLED SIC MODULE

(71) Applicant: Deere & Company, Moline, IL (US)

(72) Inventors: Christopher J. SCHMIT, Fargo, ND (US); Zachary J. WEHRI, Fargo, ND (US)

(73) Assignee: Deere & Company, Moline, IL (US)

(21) Appl. No.: 18/901,866

(22) Filed: Sep. 30, 2024

(51) Int. Cl. H01L 23/46; H01L 23/52; H01L 25/16

(52) U.S. Cl. CPC H10W 40/40; H10W 72/00; H10W 90/00; H10D 1/68

(57) ABSTRACT

A semiconductor assembly includes a semiconductor module and a unified bus. The semiconductor module a first side heatsink and a second side heatsink, a first side power device mounted to an upper surface of the first side heatsink and in electrical contact to the first side heatsink, a second side power device mounted to an upper surface of the second side heatsink and in electrical contact to the second side heatsink, and at least one cooling structure extending from a lower surface of at least one of the first side heatsink and the second side heatsink. The cooling structure is configured to provide cooling of the semiconductor module. The unified bus is communicatively connected to a capacitor assembly, the first side power device, and the second side power device. The unified bus is sintered to the first side power device and the second side power device.

### FIELD OF THE DISCLOSURE

Some example embodiments provide semiconductor assemblies, and particularly semiconductor assemblies including a semiconductor module and an integrated unified bus.

### BACKGROUND

Prior to the advent of silicon carbide (SiC) power semiconductor devices, silicon technology was limited to maximum operating temperatures of approximately 165 deg C. for very short durations and approximately 145 deg C. for somewhat extended conditions. With the introduction of SiC devices, upper temperature limits in power modules have been extended. With SiC devices, and careful build construction, it is now common to see maximum operating temperatures for very short durations of approximately 185 deg C. and approximately 165 deg C. for more extended operating conditions. These temperature limits, however, are not based on the maximum operating temperatures of the SiC device. These temperature limits are based on the package constraints of the packages the SiC devices are within.

### SUMMARY

At least one example embodiment relates to a semiconductor assembly. The semiconductor assembly includes a semiconductor module and a unified bus. The semiconductor module a first side heatsink and a second side heatsink, a first side power device mounted to an upper surface of the first side heatsink and in electrical contact to the first side heatsink, a second side power device mounted to an upper surface of the second side heatsink and in electrical contact to the second side heatsink, and at least one cooling structure extending from a lower surface of at least one of the first side heatsink and the second side heatsink. The cooling structure is configured to provide cooling of the semiconductor module. The unified bus is communicatively connected to a capacitor assembly, the first side power device, and the second side power device. The unified bus is sintered to the first side power device and the second side power device.

In an example embodiment, the first side includes a plurality of first side power devices and the second side includes a plurality of second side power devices. The unified bus is communicatively connected to each of the plurality of first side power devices and the plurality of second side power devices.

In an example embodiment, the unified bus includes a phase bus, a phase bus bridge, a positive bus, and a negative bus.

In an example embodiment, the phase bus bridge provides a connection between the phase bus and the positive bus such that the unified bus extends across the first side and the second side of the semiconductor module.

In an example embodiment, the phase bus bridge is in direct electrical contact with the plurality of first side power devices.

In an example embodiment, the negative bus is in direct electrical contact with the plurality of low side power devices.

In an example embodiment, the unified bus includes at least one layer of insulation.

In an example embodiment, the phase bus is layered between two layers of insulation.

In an example embodiment, the phase bus bridge includes a U-shaped bridge and a plurality of fingers extending therefrom. The phase bus bridge is layered between a first phase bus bridge insulation layer and a second phase bus bridge insulation layer. The plurality of fingers extend beyond the second phase bus bridge insulation layer.

In an example embodiment, the positive bus is layered between two layers of insulation.

In an example embodiment, the negative bus includes a first panel, a second panel, and a U-shaped bridge. The first and second panels extend from the U-shaped bridge. The negative bus is layered between a first negative bus bridge insulation layer and a first positive bus insulation layer, and at least the first panel extends beyond the first negative bus bridge insulation layer.

In an example embodiment, the unified bus is at least partially sintered to the semiconductor module via a silver sintering process.

In an example embodiment, the semiconductor assembly further includes a capacitor assembly communicatively coupled to the unified bus.

In an example embodiment, the semiconductor assembly of further includes an inverter base configured to house the heatsink and the capacitor assembly.

In an example embodiment, the first side power device is sintered to the first side heat sink and the first side power device is sintered to the unified bus.

In an example embodiment, the semiconductor assembly further includes a shim coupled to at least one of the first side power device and the second side power device. The shim is positioned between at least one of the first side power device and the second side power device and the unified bus.

In an example embodiment, the shim is sintered to at least one of the first side power device and the second side power device and the shim is sintered to the unified bus.

In an example embodiment, the cooling structure includes at least one of pin fins, standard fins, micro-channels, or milli-channels.

In an example embodiment, the cooling structure includes a cooling fluid such that the cooling fluid is configured to flow within the cooling structure.

At least another example embodiment relates to a bus electrically connected to a semiconductor module. The bus includes a U-shaped phase bus bridge having a plurality of fingers extending therefrom, a phase bus extending from the U-shaped phase bus bridge opposite the plurality of fingers, a positive bus electrically connected to the U-shaped bus bridge via a sintered bond between the bus and the semiconductor, and a negative bus including a U-shaped bridge corresponding with the U-shaped phase bus bridge such that the U-shaped phase bus bridge is positioned between the U-shaped bridge of the negative bus and the semiconductor module, and the positive bus is positioned between the negative bus and the semiconductor module.

At least another example embodiment relates to a semiconductor assembly (100). The assembly (100) includes a semiconductor module (200) and a unified bus (300). The semiconductor module (200) has a first side (202) and a second side (204). The semiconductor module (200) includes a first side heatsink (206a) and a second side heatsink (206b), a first side power device (212a) mounted to an upper surface of the first side heatsink (206a) and in electrical contact to the first side heatsink (206a), a second side power device (212b) mounted to an upper surface of the second side heatsink (206b) and in electrical contact to the second side heatsink (206b), and at least one cooling structure (207) extending from a lower surface of at least one of the first side heatsink (206a) and the second side heatsink (206b), the lower surface opposite the upper surface. The cooling structure (207) is configured to provide cooling of the semiconductor module (200). The unified bus (300) is communicatively connected to a capacitor assembly (400), the first side power device (212a), and the second side power device (212b). The unified bus (300) is sintered to the first side power device (212a) and the second side power device (212b).

In an example embodiment, the first side (202) includes a plurality of first side power devices (212a) and the second side (204) includes a plurality of second side power devices (212b). The unified bus (300) is communicatively connected to each of the plurality of first side power devices (212b) and the plurality of second side power devices (212a).

In an example embodiment, the unified bus (300) includes a phase bus (302), a phase bus bridge (304), a positive bus (306), and a negative bus (308).

In an example embodiment, the phase bus bridge (304) provides a connection between the phase bus (302) and the positive bus (306) such that the unified bus (300) extends across the first side (202) and the second side (204) of the semiconductor module (200).

In an example embodiment, the phase bus bridge (304) is in direct electrical contact with the plurality of first side power devices (212a), and the negative bus (308) is in direct electrical contact with the plurality of low side power devices (212b).

In an example embodiment, the unified bus (300) includes at least one layer of insulation.

In an example embodiment, the phase bus (302) is layered between two layers of insulation.

In an example embodiment, the phase bus bridge (304) includes a U-shaped bridge (316) and a plurality of fingers (322) extending therefrom. The phase bus bridge (304) is layered between a first phase bus bridge insulation layer (324) and a second phase bus bridge insulation layer (326). The plurality of fingers (322) extends beyond the second phase bus bridge insulation layer (326).

In an example embodiment, the positive bus (306) is layered between two layers of insulation.

In an example embodiment, the negative bus (308) includes a first panel (334), a second panel (336), and a U-shaped bridge (332). The first and second panels (334, 336) extend from the U-shaped bridge (332). The negative bus (302) is layered between a first negative bus bridge insulation layer (338) and a first positive bus insulation layer (328), and at least the first panel (334) extends beyond the first negative bus bridge insulation layer (338).

In an example embodiment, the unified bus (300) is at least partially sintered to the semiconductor module (200) via a silver sintering process, the first side power device (212a) is sintered to the first side heat sink (206a) via a silver sintering process, and the second side power device (212b) is sintered to the second side heat sink (206b) via a silver sintering process.

In an example embodiment, the semiconductor assembly (100) further includes a capacitor assembly (400) communicatively coupled to the unified bus (300) and an inverter base (700). The inverter base (700) is configured to house the first and second side heatsinks (206a, 206b) and the capacitor assembly (400).

In an example embodiment, the semiconductor assembly (100) further includes a shim (218) coupled to at least one of the first side power device (212a) and the second side power device (212b). The shim (218) is positioned between the power device and the unified bus. The shim (218) is sintered to at least one of the first side power device (212a) and the second side power device (212b), and the shim (218) is sintered to the unified bus (300).

In an example embodiment, the cooling structure (207) includes at least one of pin fins, standard fins, micro-channels, or milli-channels, and the cooling structure (207) includes a cooling fluid such that the cooling fluid is configured to flow within the cooling structure (207).

At least another example embodiment relates to a bus (300) electrically connected to a semiconductor module (200). The bus (300) includes a U-shaped phase bus bridge (304) having a plurality of fingers (322) extending therefrom, a phase bus (302) extending from the U-shaped phase bus bridge 9304), the phase bus (302) extending opposite the plurality of fingers (322), a positive bus (306) electrically connected to the U-shaped bus bridge (302) via a sintered bond between the bus (200) and the semiconductor module (200), and a negative bus (308) including a U-shaped bridge (332) corresponding with the U-shaped phase bus bridge (304) such that the U-shaped phase bus bridge (304) is positioned between the U-shaped bridge (332) of the negative bus (308) and the semiconductor module (300), and the positive bus (306) is positioned between the negative bus (308) and the semiconductor module (300).

### BRIEF DESCRIPTION OF THE DRAWINGS

The various features and advantages of the non-limiting embodiments herein may become more apparent upon review of the detailed description in conjunction with the accompanying drawings. The accompanying drawings are merely provided for illustrative purposes and should not be interpreted to limit the scope of the claims. The accompanying drawings are not to be considered as drawn to scale unless explicitly noted. For the purposes of clarity, various dimensions of the drawings may have been exaggerated.

FIG. 1 illustrates an exploded view of a semiconductor assembly, according to some example embodiments;

FIG. 2 illustrates an assembled perspective view of the semiconductor assembly of FIG. 1, according to some example embodiments;

FIG. 3 illustrates a cross-sectional view of the assembled semiconductor assembly of FIG. 1, according to some example embodiments;

FIG. 4A illustrates an exploded view of a module of the semiconductor assembly of FIG. 1, according to some example embodiments;

FIG. 4B illustrates an assembled view of the module of FIG. 4A, according to some example embodiments; and

FIG. 5 illustrates an exploded view of a unified bus of the semiconductor assembly of FIG. 1, according to some example embodiments.

### DETAILED DESCRIPTION

Some example embodiments will now be described more fully with reference to the accompanying drawings in which some example embodiments are illustrated.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the claims. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent”versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Prior to the advent of silicon carbide (SiC) power semiconductor devices, silicon technology was limited to maximum operating temperatures of approximately 165 deg C. for very short durations and approximately 145 deg C. for somewhat extended conditions. With the introduction of SiC devices, upper temperature limits in power modules have been extended. With SiC devices, and careful build construction, it is now common to see maximum operating temperatures for very short durations of approximately 185 deg C. and approximately 165 deg C. for more extended operating conditions. These temperature limits, however, are not based on the maximum operating temperatures of the SiC device. These temperature limits are based on the package constraints of the packages the SiC devices are within. By taking a different approach to the build construction, temperature limits of approximately 200 deg C. for short durations and approximately 185 deg C. for more longer conditions are feasible. The higher temperature limits of the package allow for more utilization of the SiC power devices' capabilities.

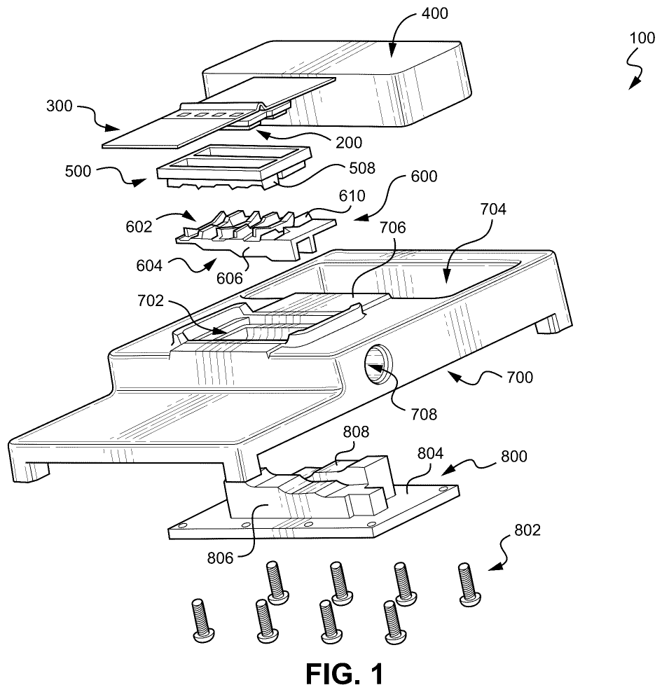

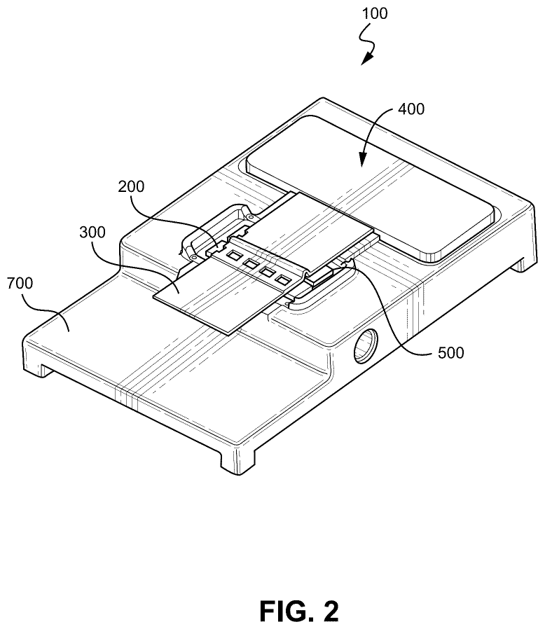

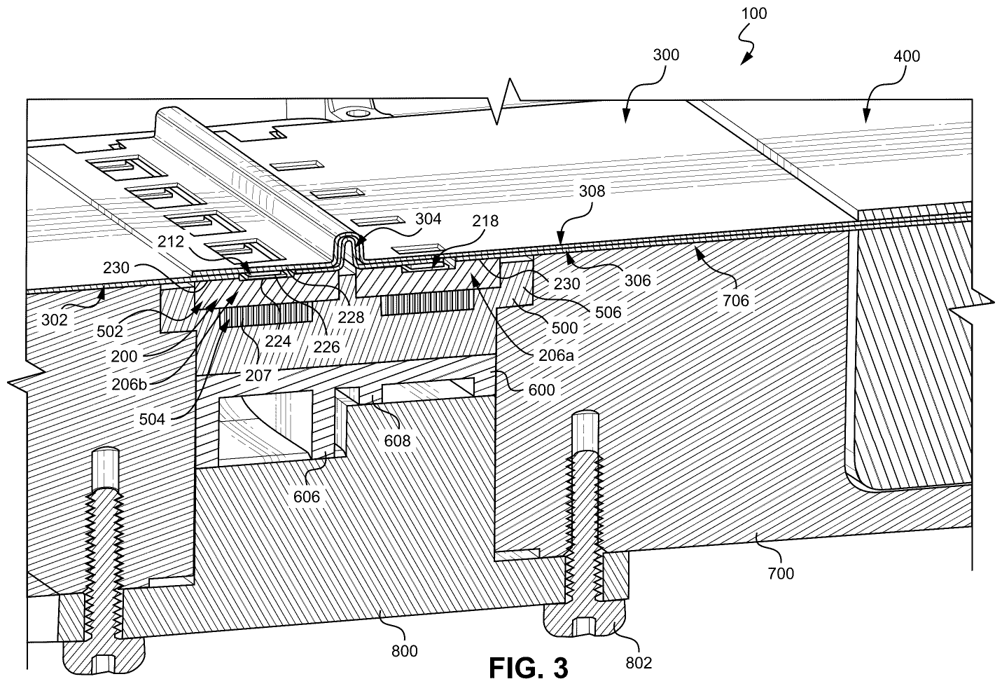

FIG. 1 illustrates an exploded view of a semiconductor assembly, according to some example embodiments. FIG. 2 illustrates an assembled perspective view of the semiconductor assembly of FIG. 1, according to some example embodiments. FIG. 3 illustrates a cross-sectional view of the assembled semiconductor assembly of FIG. 1, according to some example embodiments.

Referring to FIGS. 1-3, a semiconductor assembly 100 may include a semiconductor module 200 (e.g., module 200), a unified bus 300 (e.g., a bus 300), a capacitor assembly 400, a coolant manifold 500, a coolant diverter 600, an inverter base 700, and a coolant cover 800. The module 200, the unified bus 300, the capacitor assembly 400, the coolant manifold 500, and the coolant diverter 600 are all configured to be housed within or otherwise supported by the inverter base 700, as will be explained further herein. As described further herein, the unified bus 300 is configured to electrically connect the module 200 with the capacitor assembly 400.

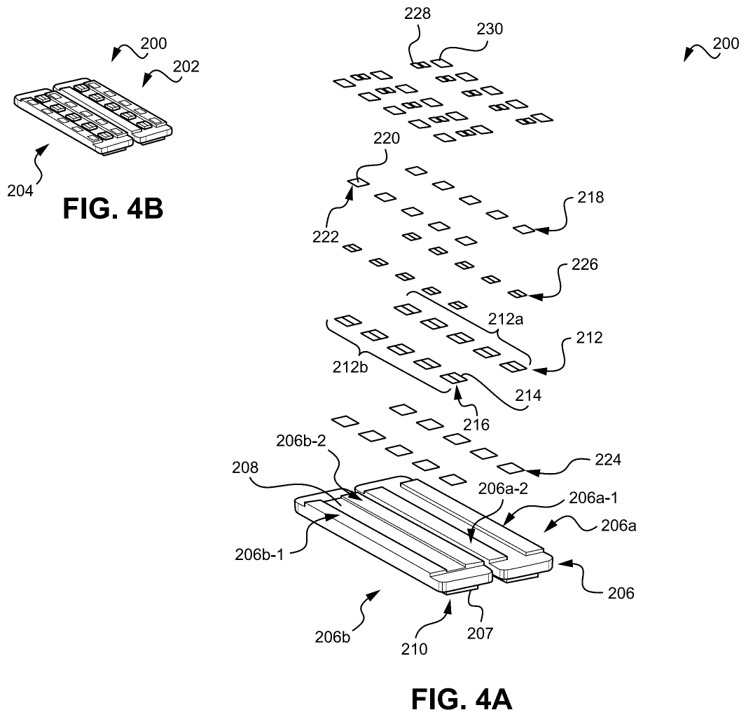

FIG. 4A illustrates an exploded view of a module of the semiconductor assembly of FIG. 1, according to some example embodiments. FIG. 4B illustrates an assembled view of the module of FIG. 4A, according to some example embodiments.

Referring to FIGS. 4A-4B, the module 200 is a single power module (e.g., a single-phase unit). However, it would be understood by a person having ordinary skill in the art that example embodiments as described herein are not limited thereto. This single unit could be multiplied inside of an inverter/converter to support multiple phases. The module 200 includes a high side power semiconductor 202 (e.g., a high side 202, or a first side 202) and a low side power semiconductor 204 (e.g., a low side 204, or a second side 204). The high side 202 and the low side 204 are put in series with respect to each other and also include paralleled semiconductor chips for multiplied current capacity. The paralleling of the semiconductor chips can be populated or de-populated as needed to meet a desired application. As used herein, a high side may refer to a side of the module 200 configured to provide electrical conductivity between a positive bus and a phase bus through a high side semiconductor, or power device, as will be explained further herein. Additionally, the high side may be referred to herein as a first side. As used herein, a low side may refer to a side of the module 200 configured for providing electrical conductivity between a negative bus and the phase base through a low side semiconductor, or power device, as will be explained further herein. Additionally, the low side may be referred to herein as a second side.

The module 200 includes a heatsink 206. The heatsink 206 includes a high side heatsink 206a (e.g., a first side heatsink 206a) and a low side heatsink 206b (e.g., a low side heatsink 206b). The high side heatsink 206a may include an outer side 206a-1 and an inner side 206a-2. The low side heatsink 206b may include an outer side 206b-1 and an inner side 206b-2, where the inner side 206b-2 of the low side heatsink 206b is adjacent the inner side 206a-2 of the high side heatsink 206a. Further, the heatsink 206 may include a die surface 208 and a cooling surface 210 opposite the die surface 208. The heatsink 206 may be constructed of silver-plated copper singular pieces.

The heatsink 206 includes a cooling structure 207. The cooling structure 207 is configured to cool the module 200. The cooling structure 207 extends from the cooling surface 210. The cooling structure 207 can include flat plate cooling, impingement spray cooling, pin fins, standard fins (e.g., manufactured by means of casting or extrusion), micro-channels, milli-channels, or other cooling features fabricated into the side opposing the power semiconductor device. The cooling structure 207 will be described further herein with additional reference to at least the coolant manifold 500, the coolant diverter 600, and the inverter base 700.

The cooling structure 207 includes a dielectric cooling fluid. In some example embodiments, the dielectric cooling fluid is transmission/hydraulic oil. However, it would be understood by a person having ordinary skill in the art that example embodiments as described herein are not limited thereto. For example, the dielectric cooling fluid may be that of many varieties, ranging from refrigerants to dielectric cooling fluids used in battery cooling to different types of synthetic and non-synthetic oils. The cooling structure 207 could be single phase cooling or two-phase cooling (e.g., liquids and liquid to gas cooling methods).

The module 200 includes a power device 212. In some example embodiments, the power device 212 may be a SiC device. In some example embodiments, the power device 212 may be Si and/or a GaN device. However, it would be understood by a person having ordinary skill in the art that example embodiments as described herein are not limited thereto. The module 200 may include a plurality of power devices 212. For example, the module 200 may include a plurality of high side power devices 212a (e.g., a plurality of first side power devices 212a) and a plurality of low side power devices 212b (e.g., a plurality of second side power devices 212b). Accordingly, the plurality of high side power devices 212a are built into the high side heat sink 206a and the plurality of low side power devices 212b are built into the low side heat sink 206b. The power device 212, or similarly the high side power device 212a and the low side power devices 212b, includes a top surface 214 and a bottom surface 216 opposite the top surface 214. The power device 212 is configured to couple to the heatsink 206. Particularly, the bottom surface 216 of the power device 212 is configured to couple to the die surface 208 of the heatsink 206. As such, heatsink 206 may be a base of the module 200.

The module 200 includes a shim 218. The shim 218 may comprise copper, silver, gold, aluminum, steel, stains steel, brass, bronze, molybdenum, or any metal (or alloy) having medium to high thermal and electrical conducting properties. The shims 218 may also include a final exterior metallic plating of copper, silver, and or gold. The shim 218 may include a top surface 220 and a bottom surface 222 opposite the top surface 220. The shim 218 may be configured to attach to the power device 212. Particularly, the bottom surface 222 of the shim 218 is configured to couple to the top surface 214 of the power device 212. Further, the top surface 220 of the shim 218 is configured to couple to the unified bus 300, as will be explained further herein.

The module 200 includes first bond 224, a second bond 226, a third bond 228, and a fourth bond 230. The first bond 224 is a sintered attachment layer between the heatsink 206 and the power device 212. The second bond 226 is a sintered attachment layer between the power device 212 and the shim 218. The third bond 228 is a sintered attachment layer between the shim 218 and the unified bus 300. The fourth bond 230 is a sintered attachment layer between the heatsink 206 and the unified bus 300, which will be explained further herein (see e.g., FIG. 3). Each bonding layer may be approximately 20-100 microns.

In some example embodiments, the top surface 220 of the shim 218 may be configured to couple to the bottom surface 216 of the power device 212. In such embodiments, the bottom surface 222 of the shim 218 may be configured to couple to the die surface 208 of the heatsink 206. In such an embodiment, a sintered attachment layer is positioned between the heatsink 206 and the shim 218, a sintered attachment layer is positioned between the shim 218 and the power device 212, and a sintered attachment layer is positioned between the power device 212 and the unified bus 300.

Similarly, in example embodiments the shim 218 may be omitted. In such embodiments, there is a sintered attachment layer between the heatsink 206 and the power device 212, and a sintered attachment layer between the power device 212 and the unified bus 300. Further, in embodiments wherein the shim 218 is omitted, the power device 212 would be coupled to the heatsink 206 and the unified bus 300 may be deformed (e.g., via a tool, a stamp, etc.) to reduce the space between the unified bus 300 and the power device 212.

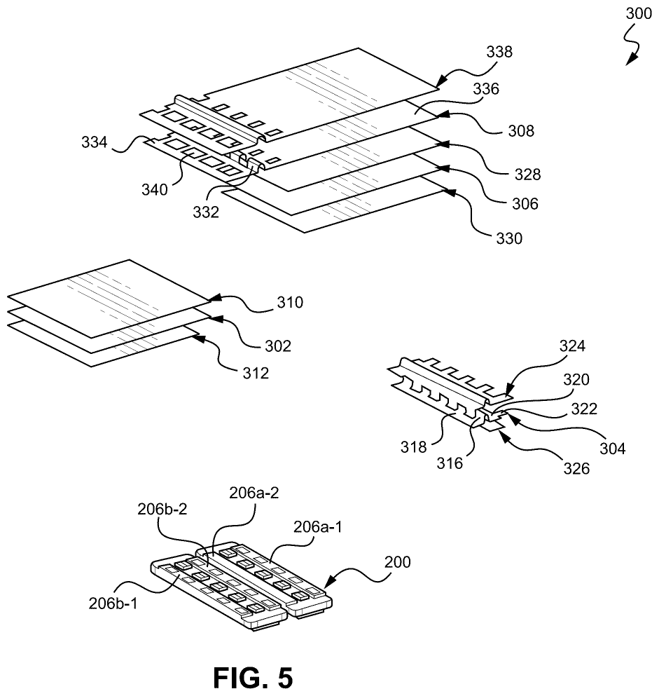

FIG. 5 illustrates an exploded view of the unified bus 300 with the assembled module 200, according to some example embodiments.

Referring to FIG. 5, the unified bus 300 includes bus work for a DC and phase side of the semiconductor assembly 100. Typically, current from the DC connection of a power module is carried to a direct bonded copper (DBC) or active metal brazing (AMB) layer via some physical connection (e.g., smaller bus bars that are a part of the connections and fusion welded to the DBC/AMB). The current then travels from the DBC/AMB to the top of the power module via bond wires. This type of connection system is then mirrored for the phase output of the power module. The bond wires typically are very limited in cross sectional area. This tends to focus the current inside of the bond wires and at the connections of the bond wires. Bond wires can often reach temperatures much higher than the power module, or the power semiconductor device (e.g., conservatively +20 deg C., in addition to the semiconductor, can be seen). These temperature excursions often limit the ultimate power of the device and create failure mechanisms. The typical failure mechanisms may be derived from high power cycling events, which end up in lifted or broken bond wires. As an alternative, if bond wires are not used inside of the power module, a “clip” may take its place. A clip is a smaller bus bar that replaces the current carrying bond wires. Clips will often be able to carry more current than bond wires. However, the use of clips includes additional sintering, soldering, or attachment methods. These additional attachment methods are typically better than bond wires but also create a limitation that is felt by the power module. Thus, by using a unified bus (e.g., the unified bus 300) to bring current to a top side of the power device (e.g., the power device 212), cross sectional area of the current carrying structure is increased as compared to bond wires or clips. Further, by using this type of configuration, at least one connection is also eliminated as compared to the use of clips. The unified bus can also be thermally connected to a heatsink (e.g., the heatsink 206) to bring down the operating temperature of the unified bus and power device. Since the bus work is of great cross-sectional area (e.g., as compared to bond wires and clips), the ability to carry heat away from the power device is enhanced. While a unified bus may operate more ideally in various applications, the use of the unified bus is not exclusive and may be used with bond wires and clips. For example, the unified bus may replace bond wires and/or clips as described herein, but the bond wires and/or clips may still exist elsewhere throughout the semiconductor assembly (e.g., within the capacitor assembly). Additionally, it would be understood by a person having ordinary skill in the art that example embodiments as described herein are not limited thereto.

Referring still to FIG. 5, the unified bus 300 includes a phase bus 302, a phase bus bridge 304, a positive bus 306, and a negative bus 308. The unified bus 300, including the phase bus 302, the phase bus bridge 304, the positive bus 306, and the negative bus 308 may include a conductive material. For example, the unified bus 300 may be a pure silver, silver-plated copper, copper (e.g., using copper sintering material as the attachment methods such as the third bond 228 and the fourth bond 230), a silver-plated aluminum or other precious or semi-precious metals such as platinum or gold.

The phase bus 302 may be a flat sheet of the conductive material. The phase bus 302 is configured to be positioned between a first phase bus insulation layer 310 and a second phase bus insulation layer 312. Each of the first phase bus insulation layer 310 and the second phase bus insulation layer 312 may be flat sheets corresponding to the phase bus 302. Once insulated between the first phase bus insulation layer 310 and the second phase bus insulation layer 312, the phase bus 302 is configured to be connected to the low side heatsink 206b (e.g., the phase heatsink). For example, the phase bus 302 may be coupled to the outer side 206b-1 of the low side heatsink 206b and extend outward therefrom.

The phase bus bridge 304 may comprise a U-shaped bridge 316, a first panel 318 extending from the U-shaped bridge 316, a second panel 320 extending from the U-shaped bridge opposite the first panel 318, and a plurality of fingers 322 extending from the second panel 320. The U-shaped bridge 316 portion of the phase bus bridge 304 is configured to absorb the stresses of the unified bus 300. For example, the unified bus 300 undergoes thermal expansion, and thus the phase bus bridge 304 allows for movement by relieving such stresses and reducing, or mitigating, the unified bus 300 from shearing off of the module 200.

The phase bus bridge 304 is configured to be positioned between a first phase bus bridge insulation layer 324 and a second phase bus bridge insulation layer 326. The first phase bus bridge insulation layer 324 may be disposed on an upper surface of the phase bus bridge 304 (e.g., a surface opposite the module 200) and may correspond with the phase bus bridge 304 in its entirety (e.g., insulate the U-shaped bridge 316, the first panel 318, the second panel 320, and the plurality of fingers 322). The second bus bridge insulation layer 326 may be configured to insulate only a portion of the phase bus bridge 304. For example, the second bus bridge insulation layer 326 may be disposed on a lower surface of the phase bus bridge 304 (e.g., a surface in contact with the module 200) and may correspond with the second panel 320.

Once insulated between the first phase bus bridge insulation layer 324 and the second phase bus bridge insulation layer 326, the phase bus bridge 304 is configured to be connected to the high side heatsink 206a (e.g., the positive heatsink) and the low side heatsink 206b (e.g., the phase heatsink). For example, the phase bus bridge 304 may be coupled to the inner side 206a-2 of the high side heatsink 206a and the inner side 206b-2 of the low side heatsink 206b. Particularly, the second phase bus bridge insulation layer 326 is positioned along the inner side 206a-2 of the high side heatsink 206a such that the plurality of fingers 322 overlap with the power device 212 (e.g., the plurality of high side power devices 212a). Accordingly, the plurality of fingers 322 are in direct electrical contact with the high side power devices 212a.

The positive bus 306 may be a flat sheet of the conductive material. The positive bus 306 is configured to be positioned between a first positive bus insulation layer 328 and a second positive bus insulation layer 330. Each of the first positive bus insulation layer 328 and the second positive bus insulation layer 330 may be flat sheets corresponding to the positive bus 306. Once insulated between the first positive bus insulation layer 328 and the second positive bus insulation layer 330, the positive bus 306 is configured to be connected to the high side heatsink 206a. For example, the positive bus 306 may be coupled to the outer side 206a-1 of the high side heatsink 206a and extend outboard therefrom.

The negative bus 308 may comprise a U-shaped bridge 332, a first panel 334 extending from the U-shaped bridge 332, and a second panel 336 extending from the U-shaped bridge opposite the first panel 334. The U-shaped bridge 332 portion of the negative bus 308 is configured to absorb the stresses of the unified bus 300. For example, the unified bus 300 undergoes thermal expansion, and thus the negative bus 308 allows for movement by relieving such stresses and reducing, or mitigating, the unified bus 300 from shearing off of the module 200.

The negative bus 308 is configured to be positioned between a first negative bus bridge insulation layer 338 and the first positive bus insulation layer 328. The first negative bus bridge insulation layer 338 may be disposed on an upper surface of the negative bus 308 (e.g., a surface opposite the module 200) and may correspond with the negative bus 308 in its entirety (e.g., insulate the U-shaped bridge 332, the first panel 334, and the second panel 336). The first positive bus insulation layer 328 may be configured to insulate only a portion of the negative bus 308. For example, the first positive bus insulation layer 328 may be disposed on a lower surface of the negative bus 308 and may correspond with the second panel 336.

Once insulated between the first negative bus bridge insulation layer 338 and the first positive bus insulation layer 328, the negative bus 308 is configured to be connected to the phase bus 302, the phase bus bridge 304 and the positive bus 306. For example, the first panel 334 may overlap the phase bus 302 and the outer side 206b-1 of the low side heatsink 206b, and may overlap the first panel 318 of the phase bus bridge 304 and the inner side 206b-2 of the low side heatsink 206b. Accordingly, the first panel 334 is also in direct electrical contact with the low side power devices 212b. The U-shaped bridge 332 of the negative bus 308 may overlap the U-shaped bridge 316 of the phase bus bridge 304. The second panel 336 of the negative bus 308 may overlap the second panel 320 of the phase bus bridge 304 and the inner side 206a-2 of the high side heatsink 206a, may overlap the plurality of fingers 322 of the phase bus bridge 304 and the power device 212, and may overlap the positive bus 306.

Although the phase bus bridge 304 does not appear to be connected to the outboard features (e.g., the phase bus 302 and the positive bus 306), because the unified bus 300 is sintered to the module 200 (e.g., the fourth bond 230), electrons between the high side power device 212a and the low side power device 212b may still be transferred via the heat sink 206.

The insulation layers described herein (e.g., the first phase bus insulation layer 310, the second phase bus insulation layer 312, the first phase bus bridge insulation layer 324, the second phase bus bridge insulation layer 326, the first positive bus insulation layer 328, the second positive bus insulation layer 330, and the negative bus bridge insulation layer 338 are configured to provide thermal insulation. Because the electrically conductive material of the unified bus 300 is so thermally conductive, the insulation layers are provided to maintain dielectric withstand of the module but also sync the heat from the power device 212 into the heatsink 206.

The unified bus 300 may further include a plurality of apertures 340. The plurality of apertures 340 is configured to facilitate a connection between the module 200 and a gate pad (not shown) such that the gate pad may communicate a signal to the module 200, indicating power on or power off commands.

Accordingly, the unified bus 300 is configured to connect to the power device 212 (e.g., via the third bond 228 sintering the shim 218 to the unified bus 300) and be directly welded into an inverter (e.g., within the capacitor assembly 400).

Referring again to FIGS. 1-3, the semiconductor assembly 100 includes the capacitor assembly 400. The capacitor assembly 400 is configured to stabilize a voltage of the DC bus while the switching events of the inverters create and use power. The capacitor assembly 400 is configured to receive the unified bus 300. In other words, the unified bus 300 is configured to extend into the capacitor assembly 400. Accordingly, the unified bus 300 is configured to be coupled to the capacitor assembly 400. In some example embodiments, the capacitor assembly 400 contains a plurality of capacitor bobbins which are directly soldered, laser welded, or otherwise electrically attached to the unified bus 300.

Referring particularly to FIG. 3, the semiconductor assembly 100 includes the coolant manifold 500. The coolant manifold 500 may be a dielectric structure. The coolant manifold 500 may comprise a high-grade engineering plastic. In other words, the coolant manifold 500 may comprise a plastic able to withstand the temperature excursions of the cooling fluid and have a high enough dielectric strength to meet the pollution degree requirements of the module. For example, the coolant manifold 500 may include a polyphenylene sulfide (PPS). In some example embodiments, the coolant manifold 500 may include other plastics such as PEK, PEEK, PSU, PES, PPSU, PAI, or other plastics.

The coolant manifold 500 may be configured to carry the heatsink 206. The coolant manifold 500 may include a first cavity 502 and a second cavity 504. The first cavity 502 may be configured to house the heatsink 206. Accordingly, the first cavity 502 may sized and shaped in accordance with the size and shape of the heatsink 206. The second cavity 504 may be configured to house the cooling structure 207. Accordingly, the second cavity 204 may sized and shaped in accordance with the size and shape of the cooling structure 207.

In some example embodiments, the heatsink 206 is sealed within the coolant manifold 500. For example, a seal (e.g., a friction seal, an O-ring, a wet bead seal, an RTV gasket, etc.) may surround the heatsink 206 when the heatsink 206 is housed within the coolant manifold 500. In some example embodiments, the coolant manifold 500 includes a dielectric material enclosing a top side of the module 200. To encapsulate and ensure passivation, a potting may be used to further encapsulate the top side of the module 200.

The coolant manifold 500 may further include at least one channel 506. The at least one channel 506 may extend along an edge of the coolant manifold 500. The at least one channel may extend adjacent to the heatsink 206. In some example embodiments, as shown in FIG. 3, the at least one channel 506 may include two channels 506. However, it would be understood by a person having ordinary skill in the art that example embodiments as described herein are not limited thereto. For example, the at least one channel 506 may include more or less than two channels 506. The at least one channel is configured to allow creepage to reduce any shock hazard to the enclosure that the coolant manifold 500 is housed in (e.g., the inverter base 700).

Referring now again to FIG. 1, the coolant manifold 500 may further include a plurality of nozzles 508. As shown, the plurality of nozzles 508 may include twelve nozzles 508 (e.g., six nozzles each aligned with the high side 202 and the low side 204). However, it would be understood by a person having ordinary skill in the art that example embodiments as described herein are not limited thereto. For example, the plurality of nozzles 508 may include more or less than twelve nozzles 508. The plurality of nozzles 508 may extend from the coolant manifold 500 toward the coolant diverter 600. Accordingly, the coolant manifold 500 may be additionally configured to divert the cooling fluid to and from the cooling structure 207, for example when working in conjunction with the coolant diverter 600, the inverter base 700, and the coolant cover 800.

The coolant diverter 600 includes an upper surface 602 and a lower surface 604 opposite the upper surface 602. The coolant diverter 600 further includes a first step formation 606 and a second step formation 608 (see FIG. 3). The direction of the incline of each of the first step formation 606 and the second step formation 608 may be opposites. In other words, the highest point of the first step formation 606 may be adjacent the lowest point of the second step formation 608, and vice versa.

The coolant diverter 600 further includes a series of diverters 610. The series of diverters 610 may extend from the upper surface 602. The series of diverters 610 may correspond with the plurality of nozzles 508 of the coolant manifold 500. For example, as shown, the series of diverters 610 may include twelve diverters 610 (e.g., six nozzles each aligned with the high side 202 and the low side 204). However, it would be understood by a person having ordinary skill in the art that example embodiments as described herein are not limited thereto. For example, the series of diverters 610 may include more or less than twelve diverters 610.

The inverter base 700 may include a first cavity 702 and a second cavity 704. The first cavity 702 is configured to house the coolant diverter 600 and the coolant manifold 500. The second cavity 704 is configured to house the capacitor assembly 400. Further the inverter base 700 may include a platform 706 configured to support the unified bus 300 as the unified bus 300 extends between the module 200 and the capacitor assembly 400. Further, the inverter base 700 includes an inlet 708. The inlet 708 may be configured to fluidly couple a coolant source (not shown) and the first cavity 702. The inverter base 700 may include an outlet (not shown) on an opposite side of the inverter base 700. The outlet may be configured to fluidly couple the coolant after it has flowed through the semiconductor assembly and a disposal area.

Generally, the coolant cover 800 is configured to close the semiconductor assembly 100. For example, as shown in FIG. 3, the coolant cover 800 may be bolted into the inverter base 700 with a plurality of coolant cover screws 802. As shown, the plurality of coolant cover screws 802 may include eight coolant cover screws 802. However, it would be understood by a person having ordinary skill in the art that example embodiments as described herein are not limited thereto. For example, the plurality of coolant cover screws 802 may include more or less than eight coolant cover screws 802. The coolant cover 800 includes an internal surface 804 (e.g., the internal surface 804 being internal to the inverter base 700 when the coolant cover 800 is coupled to the inverter base 700). The coolant cover 800 includes a first step formation 806 and a second step formation 808. The first step formation 806 and the second step formation 808 may extend from the internal surface 804 of the coolant cover 800. The direction of the incline of each of the first step formation 806 and the second step formation 808 may be opposites. In other words, the highest point of the first step formation 806 may be adjacent the lowest point of the second step formation 808, and vice versa.

Further, the coolant cover 800 is configured to interface directly with the coolant diverter 600. In order to interface directly with the coolant cover 800, the first step formation 606 and the second step formation 608 of the coolant diverter 600 mirror, coincide with, mesh with, etc. the first step formation 806 and the second step formation 808 of the coolant cover 800.

As coolant is pushed in via the inlet 708, the coolant is contained within the inverter base 700. The coolant is then forced to flow in a channel formed between the first step formation 606 of the coolant diverter 600 and the first step formation 806 of the coolant cover 800. As it leaves the coolant diverter 600, the coolant is bifurcated (e.g., partitioned, split, etc.) via the series of diverters 610. The coolant continues up through the plurality of nozzles 508 of the coolant manifold 500 which tappers and balances the flow into the second cavity 504. As the fluid flow through the cooling structure 207 as is housed in the second cavity 504, the coolant enters milli channels, for example, and is thus bifurcated again inside the milli channels. The coolant travels up and down the milli channels until it reaches an end of the path and comes back down into the coolant manifold 500 out of the milli channels. The coolant is contained again by the coolant diverter 600. As such the coolant is carried over to the next heatsink 206 (e.g., from the low side heatsink 206b to the high side heatsink 206a) and continues through a similar path through the coolant manifold 500 along the next heatsink 206 until it finds the outlet.

Referring generally to the figures, integrating the unified bus 300 with the power module 200, electrons are provided with three to four times the area, as compared to conventional methods, to move to and from the top of a source pad. Additionally, the power device 212 does not need to be isolated because the cooling structure and the accompanying cooling oil acting as an insulator allows for the power device 212 to be directly mounted to the heatsink 206. As such, manufacturing costs are reduced, along with thermal impedance. Further, by creating attachment joints via sintering, temperature concerns are reduced, and along with the enhanced heat transfer, power throughput may be increased.

Accordingly, some example embodiments described herein are directed to semiconductor assemblies including semiconductor modules with less direct bonded copper (DBC) and active metal brazing (AMB), which incorporate a unified module-inverter bus work, sintered joints, and dielectric cooling fluid. By allowing the package to utilize the SiC device capabilities, life of the module at higher operating conditions or robustness of the module is extended. Example advantages of the example embodiments are set forth herein.

For example, by elimination of the ceramic insulation layer within the module, the module thermal impedance is cut by ˜35%. As such, the temperature differential between the die and the cooling medium is reduced, and thus, the module may be pushed further (e.g., higher power throughput may be achieved) and/or be more robust in the final application. Further, a reduction in size of the power module may be achieved, which allows for higher densification of the power unit (e.g., the inverter or converter). Elimination of the DBC/AMB layer offers a cost advantage to this style of construction, as well. Because the dies typically attach to the top side of the DBC/AMB, the flatness and co-planarity of the DBC/AMB must be held to higher standards, with which comes a higher cost when considering the cost breakdown of all the module parts.

Further, by incorporating a single piece unified bus work into and extending out of the module, reduction or elimination of bond wires for power throughput, and reduction or elimination of power clips is feasible. In addition to all of the connections made inside of the power module there are also connections inside of the inverter/converter that introduce risk and losses. Therefore, by extending the bus inside of the module to the workings of the parts in the inverter/converter, bolted joints, weld joints, solder joints, and or fusion joints connecting the power module to the rest of the inverter workings (e.g., the bus capacitor and/or the phase connectors for the inverter/converter output) may be reduced or eliminated. Unification of all these pieces into a top side bus work system achieve a more robust and higher power module.

Construction of such a module includes the power semiconductor device being sintered or attached directly to the heat sinking base. In doing so the heat sinking module base also becomes electrically energized. By increasing the thickness of the sintered joint connecting the power device to the module heat sink and also tailoring the sintering density, a sinter attachment layer may double as such a buffer layer for stress reduction.

Insulation of the module is managed by insulating materials surrounding the perimeter as well as the use of a dielectric cooling fluid and passivation layers placed over a top side construction of the completed module (e.g., silicone potting covering the top side of the module 200 and the unified bus 300). The dielectric cooling fluid is allowed to make direct contact with the heat sinking module base. This stack up of materials greatly reduces the total parts/interfaces the heat flux must travel through in order to keep the module within its temperature limits.

Having described various example embodiments, it will become apparent that various modifications can be made without departing from the scope of the invention as defined in the accompanying claims.

1. A semiconductor assembly, the assembly comprising:
a semiconductor module having a first side and a second side, the semiconductor module including,
a first side heatsink and a second side heatsink,
a first side power device mounted to an upper surface of the first side heatsink and in electrical contact to the first side heatsink,
a second side power device mounted to an upper surface of the second side heatsink and in electrical contact to the second side heatsink, and
at least one cooling structure extending from a lower surface of at least one of the first side heatsink and the second side heatsink, the lower surface opposite the upper surface, the cooling structure configured to provide cooling of the semiconductor module; and
a unified bus communicatively connected to a capacitor assembly, the first side power device, and the second side power device, the unified bus being sintered to the first side power device and the second side power device.

2. The semiconductor assembly of claim 1, wherein the first side includes a plurality of first side power devices and the second side includes a plurality of second side power devices, the unified bus being communicatively connected to each of the plurality of first side power devices and the plurality of second side power devices.

3. The semiconductor assembly of claim 2, wherein the unified bus includes a phase bus, a phase bus bridge, a positive bus, and a negative bus.

4. The semiconductor assembly of claim 3, wherein the phase bus bridge provides a connection between the phase bus and the positive bus such that the unified bus extends across the first side and the second side of the semiconductor module.

5. The semiconductor assembly of claim 4, wherein the phase bus bridge is in direct electrical contact with the plurality of first side power devices.

6. The semiconductor assembly of claim 4, wherein the negative bus is in direct electrical contact with the plurality of low side power devices.

7. The semiconductor assembly of claim 3, wherein the unified bus includes at least one layer of insulation.

8. The semiconductor assembly of claim 3, wherein the phase bus is layered between two layers of insulation.

9. The semiconductor assembly of claim 5, wherein the phase bus bridge includes a U-shaped bridge and a plurality of fingers extending therefrom, the phase bus bridge being layered between a first phase bus bridge insulation layer and a second phase bus bridge layer.

10. The semiconductor assembly of claim 3, wherein the positive bus is layered between two layers of insulation.

11. The semiconductor assembly of claim 5, wherein the negative bus includes a first panel, a second panel, and a U-shaped bridge, the first and second panels extending from the U-shaped bridge, the negative bus being layered between a first negative bus bridge insulation layer and a first positive bus insulation layer, at least the first panel extending beyond the first negative bus bridge insulation layer.

12. The semiconductor assembly of claim of claim 1, wherein the unified bus is at least partially sintered to the semiconductor module via a silver sintering process.

13. The semiconductor assembly of claim 1, further comprising:
a capacitor assembly communicatively coupled to the unified bus.

14. The semiconductor assembly of claim 13, further comprising:
an inverter base configured to house the heatsink and the capacitor assembly.

15. The semiconductor assembly of claim 1, wherein the first side power device is sintered to the first side heat sink and the first side power device is sintered to the unified bus.

16. The semiconductor assembly of claim 1, further comprising:
a shim coupled to at least one of the first side power device and the second side power device, wherein the shim is positioned between at least one of the first side power device and the second side power device and the unified bus.

17. The semiconductor assembly of claim 16, wherein the shim is sintered to at least one of the first side power device and the second side power device and the shim is sintered to the unified bus.

18. The semiconductor assembly of claim 1, wherein the cooling structure includes at least one of pin fins, standard fins, micro-channels, or milli-channels.

19. The semiconductor assembly of claim 1, wherein the cooling structure includes a cooling fluid such that the cooling fluid is configured to flow within the cooling structure.

20. A bus electrically connected to a semiconductor module, the bus comprising:
a U-shaped phase bus bridge having a plurality of fingers extending therefrom,
a phase bus extending from the U-shaped phase bus bridge, the phase bus extending opposite the plurality of fingers,
a positive bus electrically connected to the U-shaped bus bridge via a sintered bond between the bus and the semiconductor module, and
a negative bus including a U-shaped bridge corresponding with the U-shaped phase bus bridge such that the U-shaped phase bus bridge is positioned between the U-shaped bridge of the negative bus and the semiconductor module, and the positive bus is positioned between the negative bus and the semiconductor module.

21.-35. (canceled)
